(19) United States
(12) Patent Application Publication
(10) Pub. No.: US 2015/0252466 A1
(43) Pub. Date: Sep. 10, 2015

(54) HIGH SURFACE AREAS (HSA) COATINGS AND METHODS FOR FORMING THE SAME

(71) Applicant: TEER COATINGS LIMITED, Droitwich (GB)

(72) Inventors: Kevin Cooke, Droitwich (GB); Sun Hailin, Droitwich (GB); Xiaoling Zhang, Droitwich (GB)

(21) Appl. No.: 14/379,696

(22) PCT Filed: Feb. 20, 2013
(86) PCT No.: PCT/GB2013/050405

§ 371 Date: Aug. 19, 2014

(30) Foreign Application Priority Data
Feb. 24, 2012 (GB) 1203216.5

(51) Int. Cl. C23C 14/35; C23C 14/14; C23C 14/20; C23C 14/16; C23C 14/18; C23C 14/02; C23C 14/58

(52) U.S. Cl. CPC C23C 14/35; C23C 14/022; C23C 14/14; C23C 14/5873; C23C 14/025; C23C 14/165; C23C 14/185; C23C 14/205

(57) ABSTRACT

The invention relates to a method of applying a coating to an article and an article with said coating. The coating is provided with at least one layer which has a surface area which is greater than the apparent or projected area of the said layer of the coating. This high surface area coating is applied in relatively high gas pressures and in one embodiment can be applied using a magnetron sputter ion plating system.

The invention which is the subject of this application relates to the generation of a coating which has or includes at least one layer with a relatively high surface area in that the said surface has a greater area than the apparent or projected area of the surface.

The provision of coatings on articles to provide protection and/or specific features or characteristics for the article is well known and the particular composition and/or features of the coating can be selected to achieve specific functions and/or performance.

In many cases the coatings are applied with the main aim being to ensure that the thickness and/or composition of the coating meets predetermined requirements but it is known to be difficult to effectively apply coatings in which the surface area of the coatings can be increased to provide a more effective characteristic of the coating to be achieved.

The aim of the present invention is to provide a coating with an external surface which is formed so as to provide specific advantages in use of the coating and article to which the same has been applied. A further aim is to provide a method of applying such a coating which allows the required control of the formation of the characteristics of the external surface.

In a first aspect of the invention there is provided an article with a coating applied to at least a portion of the same, said coating including at least one layer which has a surface area which is greater than the apparent or projected area of the said layer of the coating.

In one embodiment the said surface area is at least 30 times greater than the apparent or projected area.

In one embodiment the apparent or projected area of the said layer is that which is calculated using the length and width of the said layer. Typically the same can be regarded as the area of the surface when substantially smooth.

In one embodiment the said at least one layer of the coating on which the high surface area is provided forms the external surface of the coating.

In one embodiment the coating includes at least one further layer which is formed to be denser than the layer of material which is provided with the high surface area.

In another embodiment the said layer with the high surface area is provided within the coating with at least one further layer of material applied over the same.

In one embodiment the coating has a grain size in the range of 3 to 100 nm, with a layer thickness in the range of 50 nm to 10 μm, and preferably in the range 50 nm to 3.0 μm.

In one embodiment the coating is composed of a single element. In an alternative embodiment the coating is composed of multiple combinations of metal, semi-metals, ceramics and mixtures thereof.

In one embodiment the coating is applied to an article to enable and/or improve the use of the article for any, or any combination of, catalytic, photo-catalytic, anti-reflection, antibacterial, sensors, filters, pyrophoric devices, hydrophobic surfaces, biomedical prostheses and/or thermal barrier functions.

In one embodiment the surface finish is provided to enhance the characteristics of the material used to form the coating.

In one embodiment the material applied is an oxide such as Titanium Oxide, Nickel Oxide or Copper Oxide and the Surface area is controlled so as to enhance the hydrophilicity of the coating.

In a further aspect of the invention there is provided a method for the application of a coating, said method including the steps of placing the article to be coated on a holder, selectively operating one or more material deposition means to deposit material therefrom onto the said article to form the coating and wherein during the application of at least one layer of the coating the material deposition means are operated to create said at least one layer with a surface area which is greater than the apparent or projected area of the surface of the layer.

In one embodiment the coating is applied by physical vapour deposition.

In another embodiment the coating is applied by depositing the material to form the coating at a high rate using magnetron sputtering.

Typically the magnetron targets from which material is deposited and the article onto which the material is to be deposited is such that the direction of travel of the sputtered material at the time of impact on the article is not at 90 degrees to the surface of the article. In one embodiment the angle of impact is in the range of 50-70 degrees.

Typically the magnetron arrangement within the coating apparatus is operated in an open field or so-called “mirrored field” manner at least when the material for forming the High Surface Area layer of the coating is applied.

In one embodiment the coating applied includes nickel in which the High Surface Area is created. In one embodiment the coating is an alloy of nickel and molybdenum, e.g. NiMo.

In one embodiment the material used to form at least the high surface area layer of the coating is a metal alloy and the same is subsequently treated to remove an element of the metal alloy to create a labyrinth effect in the High Surface Area coating, in a similar approach to the so-called Raney metals (after M. Raney, U.S. Pat. No. 1,628,190 (1927).

In one embodiment the coating is applied by depositing the material in a selected gas, successive gases or mixture of gases so as to form the required coating. Preferably the material to form at least the high surface area layer of the coating is applied with helium present in the coating environment.

In one embodiment the gases are provided at a total pressure within the range of between 2.0×10⁻³ mbar and 1.5×10⁻² mbar, and preferably in the range 1.0×10⁻² mbar to 1.5×10⁻² mbar.

In one embodiment the gas pressure during deposition of material to form the coating is maintained at a constant value.

In one embodiment the gas pressure during deposition of material to form the coating is varied.

In one embodiment the temperature of the substrate during deposition is maintained in the range 100 to 1000° C., to encourage diffusion of the coating material into the substrate surface.

Typically the above parameters are controlled during deposition in order to ensure that the coating adheres to the surface of the article to which the same is being applied and also that the required high surface area of the external surface of the coating is achieved.

In one embodiment the coating is selected to create a nucleation (“seed”) density in a metal, preferably one with a high melting point, in order to achieve a coating with nucleated grains in the range of 10,000 to 25000 per μm².

In one embodiment a further coating of, for example, as a continuous, conformal layer or as discrete particles of a catalytic material, for example a platinum group metal (PGM) or a compound thereof, may be deposited on top of the high surface area coating in order to further enhance the overall catalytic performance of the coated surface.

In one embodiment the coating is applied to an article formed from any, or any combination of steel, stainless steel, aluminium and its alloys, titanium and its alloys, polymers, ceramic, carbon cloth, glass, rubber and/or wood.

Typically the article may be electrically conductive and in this case the coating typically includes one or more layers of relatively dense coating material.

In one embodiment the article on which the coating is applied is provided in a form which is appropriate for its purpose, such as any or any combination of a flat surface, a mesh, a powder, a fibre, and/or particles.

In a further aspect of the invention there is provided a method for the application of a coating, said method including the steps of placing the articles to be coated on a holder, selectively operating one or more magnetrons to deposit material therefrom onto the said articles to form the coating and wherein at least during the application of one layer of the coating the magnetrons used are provided to create an open field sputtering environment in order to create the said layer with a surface area which is greater than the apparent or projected area of the surface of the layer.

A specific embodiment of the invention is now described with reference to the accompanying drawings; wherein

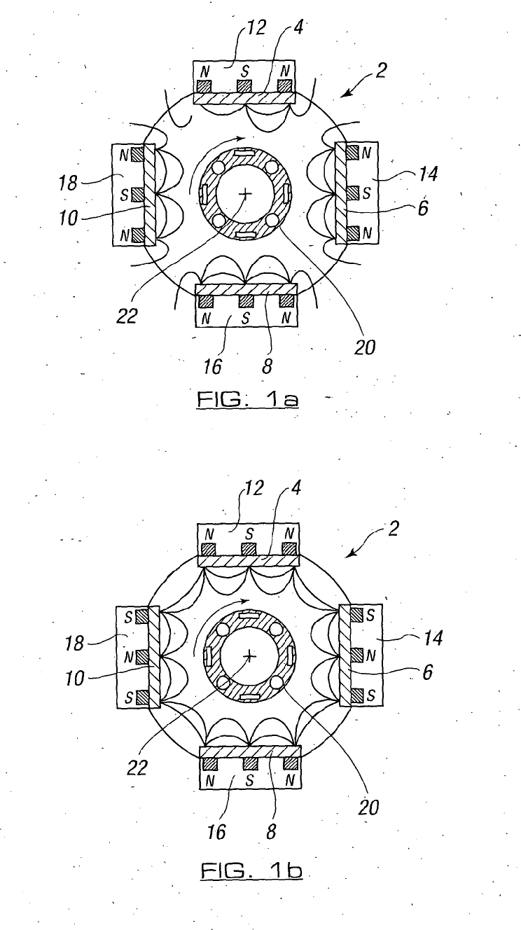

FIGS. 1a and b illustrate open and closed field magnetron sputtering apparatus of a type which can be used in the application of coatings in accordance with the invention;

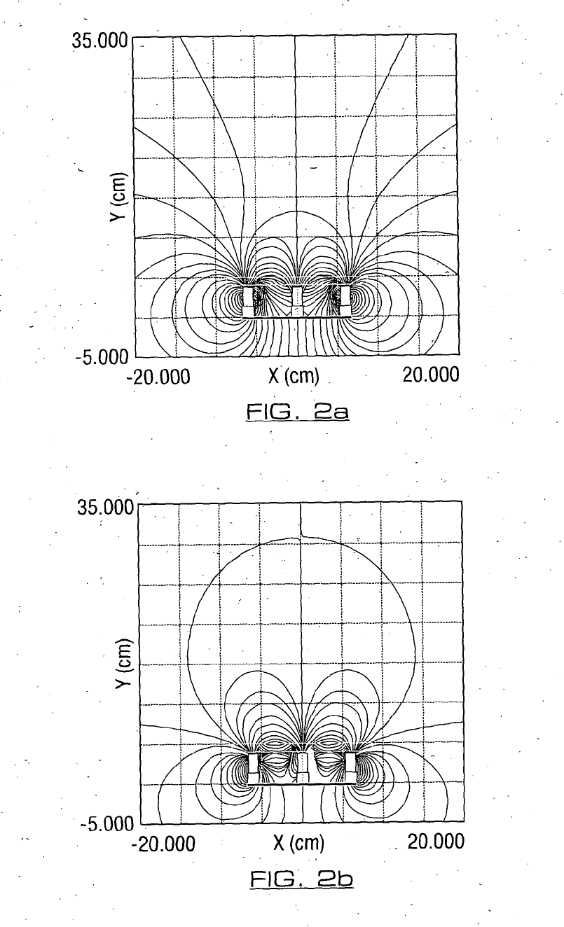

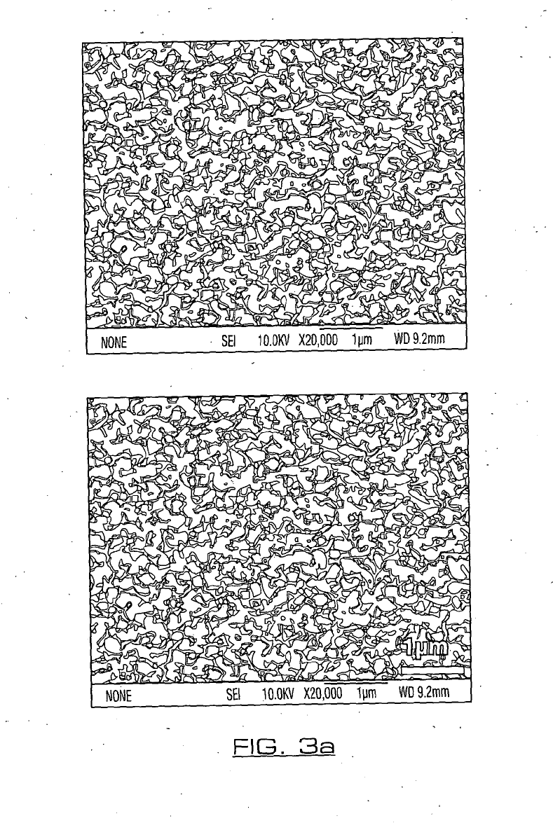

FIGS. 2a and b illustrate simulations of magnetic field distributions of type I and type II unbalanced magnetrons;

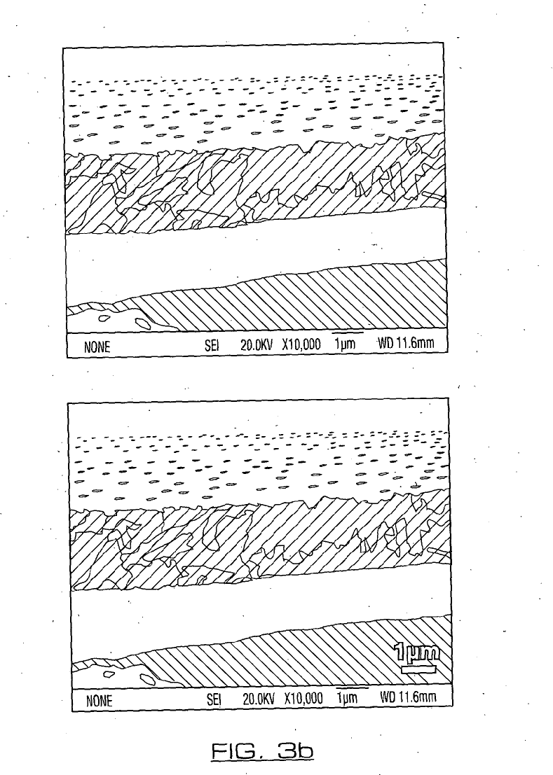

FIGS. 3a and b illustrate views of a high surface area nickel alloy coating applied in accordance with one embodiment of the invention;

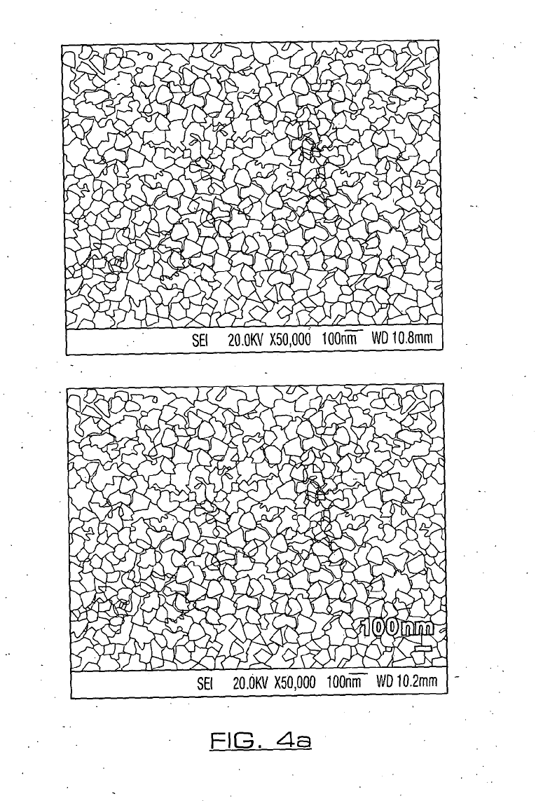

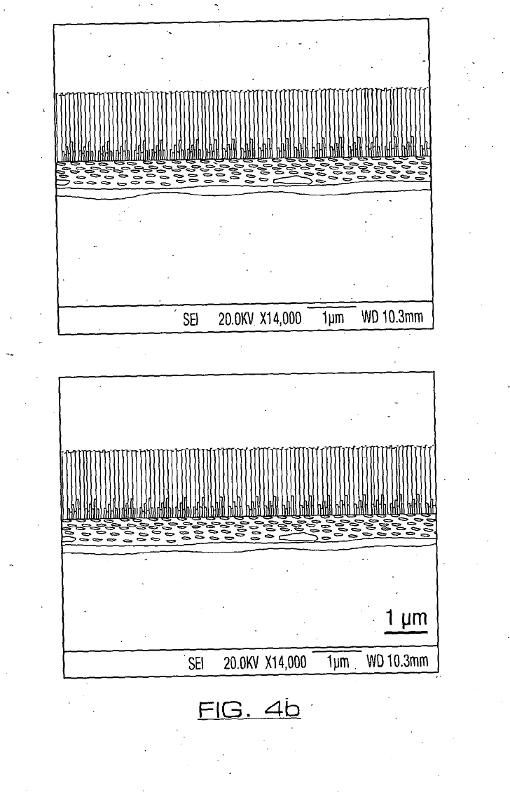

FIGS. 4a and b illustrate views of a high surface area nickel alloy coating with a dense under layer and high surface area top layer in accordance with another embodiment of the invention;

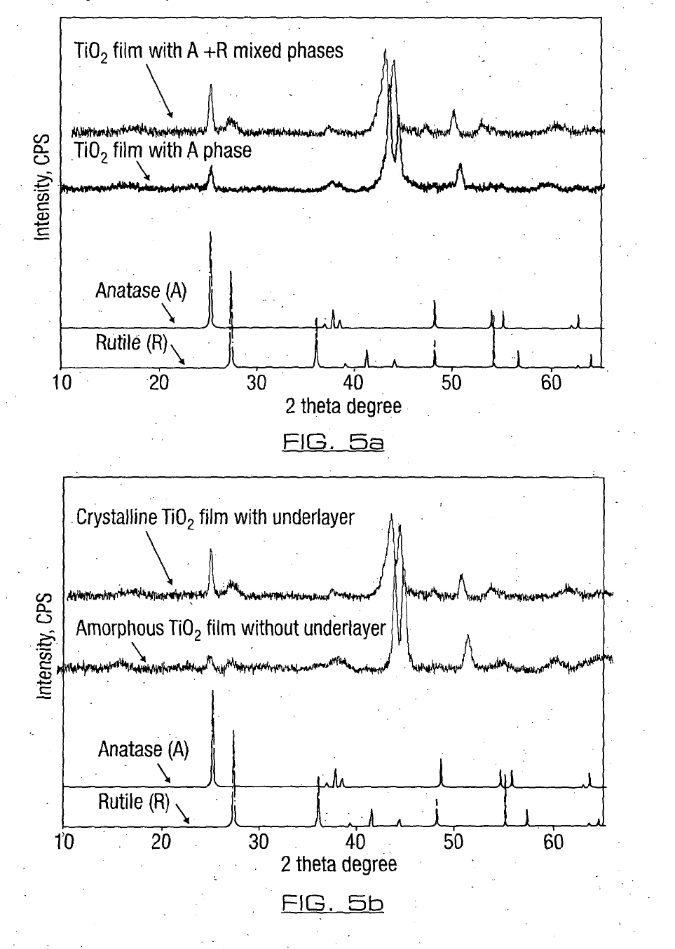

FIGS. 5a-c illustrate graphically and photographically a TiO₂ coating with a High Surface Area in accordance with a further embodiment of the invention.

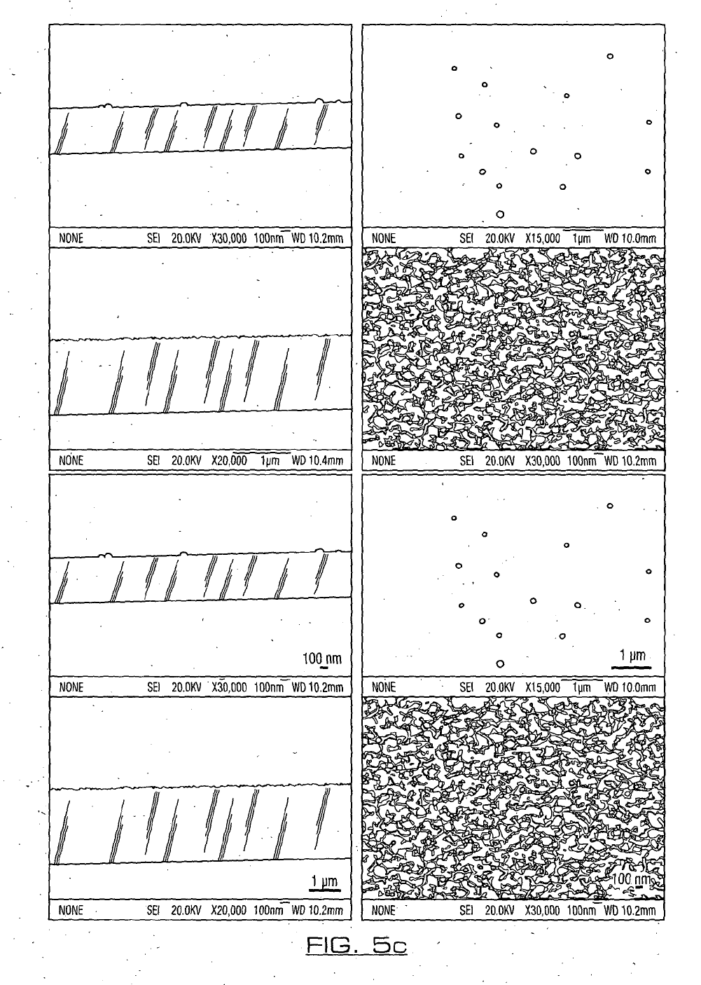

FIGS. 6a and b illustrate Ni alloy nano-clusters with the size of ˜3 to 10 nm in accordance with the invention; and

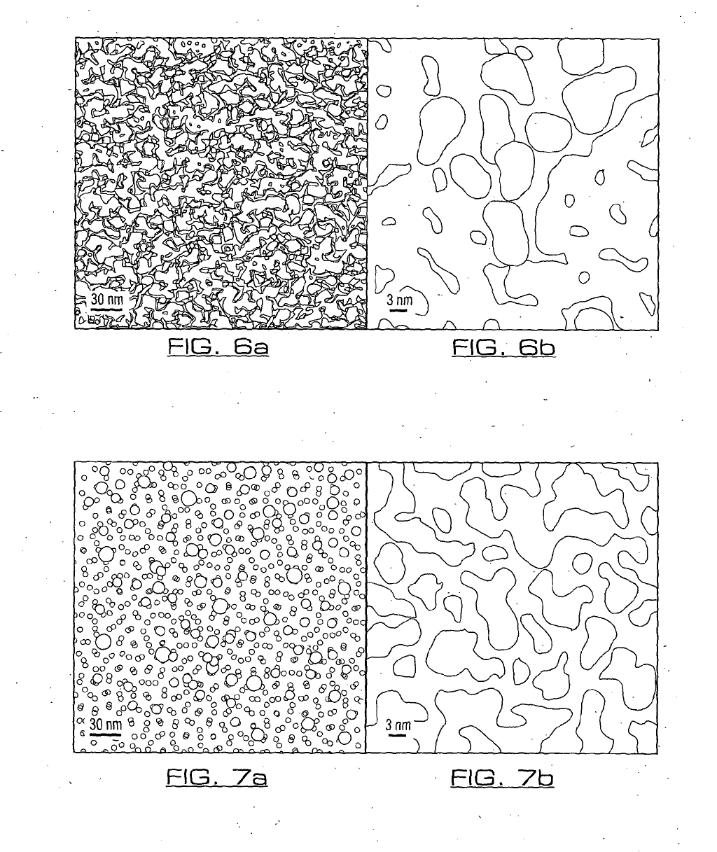

FIGS. 7a and b illustrate Ni alloy nano-clusters with the size of typically less than or equal to ˜3 nm in accordance with the invention.

In one embodiment of the invention the High surface area coatings are deposited using a magnetron sputter ion-plating system 2 of the type shown in FIGS. 1a and b. Four metal, alloy, carbon or compound targets, 4,6,8,10, selected as required for the coating to be formed, are mounted in respective magnetrons 12, 14, 16, 18 located within a chamber. The magnetrons are selectively operated to sputter deposit the material from the selected targets to form the coating on the articles which are held on a holder 20 which is rotatable, as indicated by arrow 24 about a central axis 22. During the sputtering of the material, argon, or argon plus helium are introduced into the chamber to allow pure magnetron sputtering depositions; and oxygen, nitrogen or a hydrocarbon gas are introduced into the chamber to act as reactive gases to allow reactive sputtering depositions.

In this example, the distance between the targets and the articles when held on the holder is in the region of 100-170 mm. During the coating process the substrates can either be kept still or rotated to pass the targets at a controlled rotation speed.

Preferably the substrates were cleaned, before coating, in a dedicated cleaning solvent with or without ultrasonic agitation and completely dried. They were placed into the coating chamber which was then pumped down to a pressure of typically lower than 2.5×10⁻⁵ mbar.

The substrates were then plasma-ion-cleaned prior to deposition with an argon pressure of 4.0×10⁻³ mbar, and an average, approximately −400 V bias with a pulsed direct current (DC) power supply of 250 kHz pulse frequency and 500 ns pulse duration, i.e. a duty cycle of approximately 87.5%.

Preferably a high deposition pressure e.g. 60˜130 mbar; is provided with the use of an argon and helium mixture as a working gas, e.g. Ar/He=1:1˜1:2 (which is the ratio of gas flows, controlled via individual mass flow controllers) is used. The use of relatively high pressure gases in the coating chamber allows the formation of the high surface area layer of the coating to be achieved efficiently and in a controlled manner. Also provided in the chamber are magnetrons 12, 14, 16, 18 which are typically provided of a type to be operated in an open magnetic field manner, as shown in FIG. 1a. This form of apparatus was used to apply the coating with the High Surface Area in accordance with one embodiment of the invention. Preferably Type I unbalanced magnetrons were used and these are provided in a magnetic field as illustrated in FIG. 2a. A bias at a floating potential was provided on the articles on the holder, and these are the preferred deposition conditions to achieve a coating with a high surface area surface in accordance with the invention.

One such coating, applied using the apparatus as described, and which coating is provided with a porous high surface area structure is illustrated in FIGS. 3a and b which show the surface and fracture cross section of a nickel alloy coating with a high surface area which has been applied to an article.

It is found that a coating thickness of 20 nm to tens of microns can be achieved by controlling the duration of deposition of the material using the apparatus and that the surface area of such a coating is more than 30 times greater than that of the apparent or projected area of the surface of the article to which the coating has been applied.

In certain instances it may be desirable to apply a coating which has a high surface area on its external surface and also has other required properties such as in order to protect the article to which it has been applied from corrosion and other physical and chemical degradation processes. An example of such a coating is shown in FIGS. 4a and b. In this case the coating includes a combined dense underlayer with a high surface area top layer. The coating can be deposited in one process with the dense underlayer being applied using the apparatus described previously but operating in a closed field configuration as illustrated in FIG. 1b and using type II magnetrons to create the closed magnetic field illustrated in FIG. 2b. In this case the dense underlayer can be deposited with argon as a working gas at a pressure of 1˜7 mbar and −35˜−55 V bias followed by the operation of the apparatus in a n open field configuration as described previously to apply the top layer with the High Surface Area.

It is possible to combine the two deposition environments described above in a single process, either by employing magnetrons with variable magnetic configurations, such as increasing or reducing the strength of the central magnetic poles by having those magnets on a moveable support, or by arranging separate deposition chambers equipped with the two different deposition environments respectively, in order to deposit the dense coating layer or layers and the high surface area porous layer or layers.

In one embodiment the application of the high surface area coatings in accordance with the invention can be integrated into large scale production environments with different magnetron configurations provided and used in separate coating chambers with, for example, the closed field magnetron configuration combined with type II unbalanced magnetrons being used for plasma-ion-cleaning of the articles and the deposition of the relatively dense coating layers; and the open field magnetron system with type I unbalanced magnetrons used for the deposition of the high surface area layer or layers in another chamber.

It is possible to apply oxides, nitrides, carbides or other composite coatings with the high surface area and, in order to enhance the adhesion of the coating, a thin metal layer can first be deposited by DC magnetron sputtering using argon or argon plus helium as working gases. The metal layer which is applied can be dense or porous as shown above depending on the particular application requirement. However it should be noted that the application of the oxides, nitrides or carbides to form the coating without an adhesion layer of metal is possible, particularly if the coating adhesion is not an issue or no metal interlayer is needed.

The final oxides, nitrides or carbide coating can be deposited by reactive sputtering with oxygen, nitrogen or butane gases present in the chamber and the flow rate of the reactive gases is controlled, in one embodiment via an optical emission monitoring (OEM) system linked to a fast acting piezo-valve. A pulsed DC power supply provides ˜45 V˜−70 V bias on the substrates during deposition processes and the duration of the deposition time is controlled with reference to the required coating thicknesses.

FIG. 5a shows two typical XRD patterns of crystallized TiO₂ coatings achieved in accordance with the invention.

In a further embodiment the invention can provide a coating in which the high surface area metal layer is provided as an underlayer. The provision of the underlayer in this form can be used to increase the catalytic properties of the top compound layer and/or promote the crystallization of the deposited top compound layers.

FIGS. 5b and 5c show the crystallized TiO₂ coatings deposited on to a high surface area NiMo underlayer. In contrast, TiO₂ coatings deposited without NiMo underlayer is in amorphous structure.

Additional heating, or positive bias can be applied on the substrates during depositions, a closed field magnetron system, high power type II unbalanced magnetron, higher power supply or HIPIMS can be used to obtain crystallised high surface area compound coatings if required.

In certain cases the high surface area compound coatings which are deposited can have amorphous structures and, if required, heat treatment after deposition can be used to obtain crystallized structures.

FIGS. 6a-b and 7a-b illustrate examples of nickel alloy nano-clusters produced under the high surface area deposition conditions described above and the particle size is typically in the range of 3˜10 nm. Particles with controlled sizes can be deposited by varying deposition conditions and two examples of the same are illustrated in FIGS. 6a-b and 7a-b respectively. Such particles can be deposited on to flat surfaces, meshes, powders, fibres and particles and this represents an efficient way of producing nano-particles in comparison with using nano-cluster beam generators.

There is therefore provided a method and apparatus in accordance with the invention which allows the application of a coating with at least a layer which has a high surface area, in an efficient and repeatable manner.

1: An article with a coating applied to at least a portion of the same, said coating including at least one layer which has a surface area which is greater than the apparent or projected area of the said layer of the coating.

2: An article according to claim 1 wherein the said surface area is at least 30 times greater than the said apparent or projected area.

3: An article according to claim 1 wherein the apparent or projected area of the said at least one layer is defined as the area of an equivalent homogeneous coating, fully conformal with the surface of the article.

4-5. (canceled)

6: An article according to claim 1 wherein the said at least one layer is provided within the coating with at least one further layer of material applied over the same.

7: An article according to claim 1 wherein the coating has a grain size in the range of 3 to 100 nm.

8: An article according to claim 1 wherein the coating has a layer thickness in the range of 50 nm to 10 μm.

9-10. (canceled)

11: An article according to claim 1 wherein the coating is composed of any, or any combination, of metal, semi-metals, and/or ceramics.

12: An article according to claim 1 wherein the coating is applied to the article to enable and/or improve the use of the article for any, or any combination of catalytic, photo-catalytic, anti-reflection, antibacterial, sensors, filters, pyrophoric devices, hydrophobic surfaces, biomedical prostheses and/or thermal barrier functions.

13: An article according to claim 1 wherein the said at least one layer includes nickel.

14-15. (canceled)

16: An article according to claim 1 wherein the said at least one layer is provided as a labyrinth.

17: An article according to claim 1 wherein at least part of the coating is applied in one or more gases at a total pressure within the range of between 2.0×10⁻³ mbar and 1.5×10⁻² mbar.

18. (canceled)

19: An article according to claim 1 wherein the coating includes an underlayer with a further layer having a high surface area.

20: A method for the application of a coating, said method including the steps of placing the article to be coated on a holder, selectively operating one or more material deposition means to deposit material therefrom onto the said article to form the coating and wherein during the application of at least one layer of the coating the material deposition means are operated to create said at least one layer with a surface area which is greater than the apparent or projected area of the surface of the layer.

21: A method according to claim 20 wherein the coating is applied using physical vapour deposition including magnetron sputtering.

22. (canceled)

23: A method according to claim 22 wherein a plurality of magnetrons are provided and at least one of the magnetrons is selectively operated to deposit material therefrom onto the said article and at least during the application of the said at least one layer the magnetrons are operated in an open field or mirrored field sputtering environment.

24: A method according to claim 20 wherein at least during the application of the said at least one layer, the targets of the magnetrons from Which material is deposited and the article onto which the material is to be deposited are respectively arranged such that the direction of travel of the sputtered material at the time of impact on the article is other than 90 degrees to the surface of the article.

25. (canceled)

26: A method according to claim 21 wherein the said at least one layer is formed at least partially by depositing a nickel containing material.

27. (canceled)

28: A method according to claim 20 wherein the said at least one layer is formed from a metal alloy, and treating the same to remove at least one element of the metal alloy in order to create the said at least one layer with a labyrinth effect.

29: A method according to claim 20 wherein the said coating is applied by depositing material in a selected gas, successive gases or mixture of gases so as to form the required coating.

30. (canceled)

31: A method according to claim 28 wherein the gases are provided at a total pressure within the range of between 2.0×10⁻³ mbar and 1.5×10⁻² mbar.

32-34. (canceled)

35: A method according to claim 20 wherein the temperature of the substrate during deposition is maintained in the range 100 to 1000° C., to encourage diffusion of the coating material into the substrate surface.

36: A method according to claim 20 wherein the coating is applied to create a nucleation (“seed”) density in a metal, in order to achieve a coating with nucleated grains in the range of 10,000 to 25000 per μm².

37: A method according to claim 36 wherein a further coating is deposited on top of the said coating to enhance the overall catalytic performance of the coated surface.

38: A method according to claim 37 wherein the said further coating is in the form of a continuous, conformal layer.

39: A method according to claim 37 wherein the said further coating is in the form of discrete particles of a catalytic material.

40: A method according to claim 36 wherein the coating is applied to an article formed from any, or any combination, of steel, stainless steel, aluminum and its alloys, titanium and its alloys, polymers, ceramic, carbon cloth, glass, rubber and/or wood.

41: A method according to claim 40 wherein the coating includes an underlayer with a further layer having a high surface area.

42: A method according to claim 41 wherein the underlayer is applied using magnetron deposition apparatus in a closed field configuration and the said top layer is applied using the apparatus in an open field configuration.

43: A method for the application of a coating, said method including the steps of placing the articles to be coated on a holder, selectively operating one or more magnetrons to deposit material therefrom onto the said articles to form the coating and wherein at least during the application of one layer of the coating the magnetrons used are provided to create an open field sputtering environment in order to create the said layer with a surface area which is greater than the apparent or projected area of the surface of the layer.
